(19) United States
(12) Patent Application Publication
(10) Pub. No.: US 2010/0093162 A1
(43) Pub. Date: Apr. 15, 2010

(54) Method of manufacturing semiconductor device

(75) Inventor: Tomohiro Yakuwa, Miyagi (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/585,849

(22) Filed: Sep. 25, 2009

(30) Foreign Application Priority Data
Sep. 26, 2008 (JP) 2008-248330

(51) Int. Cl. H01L 21/26

(52) U.S. Cl. 438/527; 257/E21.328

(57) ABSTRACT

A method of manufacturing a semiconductor device wherein semiconductor elements (e.g., transistors) respectively formed in multiple independent wells have the same characteristics with the number of production process steps being reduced. A P-type well as an area of a first conductivity type is formed on a semiconductor substrate. Then, second and fourth wells as two regions of a second conductivity type are formed apart from each other in the P-type well, and a first buried well of N-type as a first buried region of the second conductivity type to connect the second and fourth wells is formed at the bottom of a third well (part of the area of the first conductivity type) sandwiched between the second and fourth wells. In this way, a triple well is formed on the semiconductor substrate.

### BACKGROUND OF THE INVENTION

1. Field of the Invention

The present invention relates to a method of manufacturing a semiconductor device and particularly to a manufacturing method which forms triple wells (wells of a triple structure).

2. Description of the Related Art

Conventionally, in semiconductor devices such as operational amplifiers (inverting amplifying circuits) outputting an output signal of high voltage, a voltage range of Vss to Vdd is usual. Refer to, for example, Japanese Patent Kokai No. 2007-116497, FIG. 1, etc. (Patent Literature 1). However, because each amplifier operates in a wide voltage range, its heat generation becomes large, which constitutes an unneglectable problem.

Accordingly, amplifiers capable of operating with low heat generation by using amplifiers having their voltage range reduced in half in combination are being examined. Refer to, for example, Japanese Patent Kokai No. H10-062744, FIGS. 9, 10, etc. (Patent Literature 2).

Introducing the above technology results in voltage ranges in plurality, and multiple power supplies each connecting to transistors to operate in a respective voltage range are necessary. Hence, multiple independent wells need to be formed in a silicon substrate. As techniques for forming multiple independent wells, proposed are, for example, a technique for forming double wells (wells of a double structure), disclosed in, e.g., Japanese Patent Kokai No. H05-198666 (Patent Literature 3), and a technique for forming triple wells (wells of a triple structure), disclosed in, e.g., Japanese Patent Kokai No. H10-199825 (Patent Literature 4).

In particular, as proposed in Patent Literature 4, with the technique for forming triple wells (wells of a triple structure), there are the problems that the process is complicated and that because multiple independent wells are formed individually, semiconductor elements (e.g., transistors) formed in the wells differ in performance.

### SUMMARY OF THE INVENTION

Accordingly, an objective of the present invention is to provide a method of manufacturing a semiconductor device such that semiconductor elements (e.g., transistors) respectively formed in multiple independent wells have the same characteristics with the number of production process steps being reduced.

The above objective has been attained by the following measures.

According to a first aspect of the present invention, a method of manufacturing a semiconductor device comprises the steps of forming an area of a first conductivity type on a semiconductor substrate; forming two regions of a second conductivity type apart from each other in the area of the first conductivity type; and forming a first buried region of the second conductivity type to connect the two regions of the second conductivity type at the bottom of part of the area of the first conductivity type sandwiched between the two regions of the second conductivity type that are spaced apart.

According to a second aspect of the invention, a method of manufacturing a semiconductor device according to the first aspect of the invention, further comprises the step of forming a second buried region of the first conductivity type to connect the two regions of the second conductivity type above the first buried region of the second conductivity type at the bottom of the part of the area of the first conductivity type sandwiched between the two regions of the second conductivity type that are spaced apart.

According to a third aspect of the invention, in a method of manufacturing a semiconductor device according to the first aspect of the invention, the first buried region is formed by implanting phosphorus (P) at a concentration of 5×10¹² cm⁻² or greater at an energy of 1.6 MeV to 2.2 MeV.

According to a fourth aspect of the invention, in a method of manufacturing a semiconductor device according to the second aspect of the invention, the second buried region is formed by implanting boron (B) at a concentration of 2×10¹² cm⁻² to 5×10¹² cm⁻² at an energy of 300 keV to 500 keV.

According to a fifth aspect of the invention, in a method of manufacturing a semiconductor device according to the first aspect of the invention, a carrier surface concentration has no difference between a region of the area of the first conductivity type formed on the semiconductor substrate, sandwiched between the two regions of the second conductivity type that are spaced apart, and another region of said area of the first conductivity type.

According to the present invention, there is provided a method of manufacturing a semiconductor device wherein transistors respectively formed in multiple independent wells have the same characteristics with the number of production process steps being reduced.

### BRIEF DESCRIPTION OF THE DRAWINGS

FIGS. 1A to 1E are a process chart showing the method of manufacturing a semiconductor device according to a first embodiment;

FIGS. 2A to 2C are a process chart showing the method of manufacturing a semiconductor device according to a second embodiment; and

FIG. 3 is a diagram that shows the carrier concentration profile along line X-X′ of a first well and the carrier concentration profile along line Y-Y′ of a third well in a triple well obtained by the method of manufacturing a semiconductor device according to the second embodiment.

### DETAILED DESCRIPTION OF THE INVENTION

Illustrative embodiments of the present invention will be described below with reference to the accompanying drawings. The same reference numerals are used to denote substantially the same or like parts in function throughout all the drawings, and duplicate description thereof may be omitted.

### First Embodiment

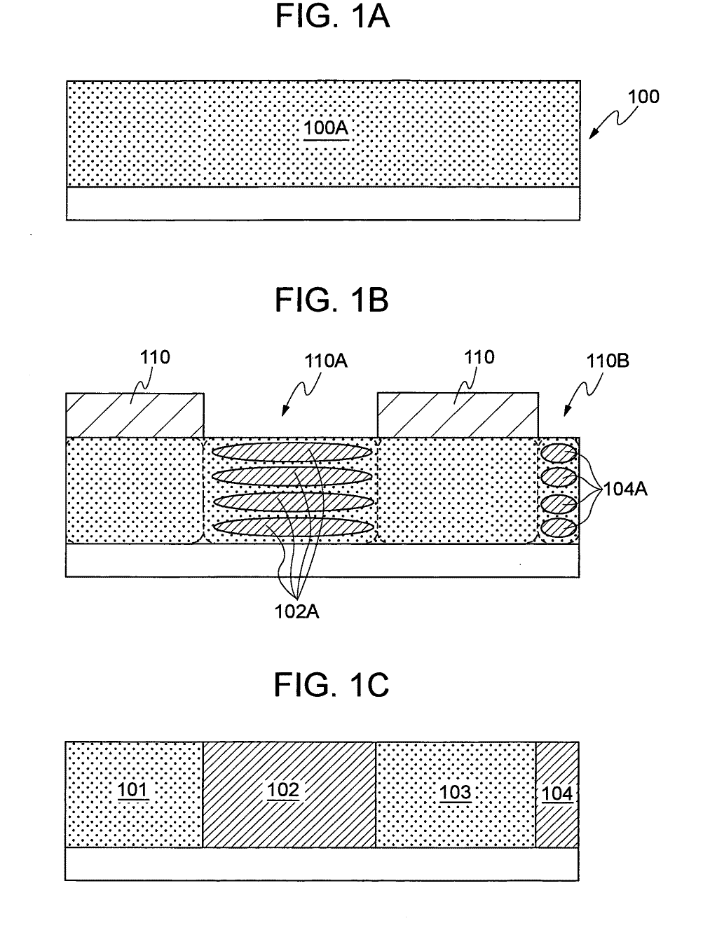

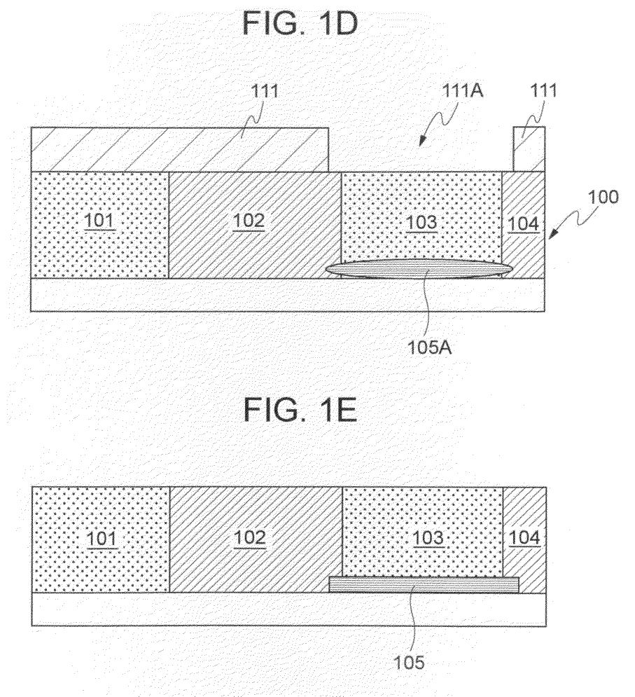

FIGS. 1A to 1E are a process chart showing the method of manufacturing a semiconductor device according to a first embodiment.

In the method of manufacturing a semiconductor device according to the first embodiment, first a P-type semiconductor substrate 100 is prepared as shown in FIG. 1A, and the P-type ions are implanted into the entire surface of the P-type semiconductor substrate 100 to form a P-type well 100A.

Next, a resist 110 having openings 110A, 110B apart from each other is formed over the surface of the P-type well 100A formed in the semiconductor substrate 100 as shown in FIG. 1B. This resist 110 is formed on parts of the surface of the P-type well 100A to become a first well 101 of P-type and a third well 103 of P-type, exposing a part of the surface of the P-type well 100A through its opening 110A, which part is to become a second well 102 of N-type and a part of the surface of the P-type well 100A through its opening 110B, which part is to become a fourth well 104 of N-type.

Then, N-type ions are implanted through the openings 110A, 110B of the resist 110, e.g., two or three times consecutively, each time at a different energy to form N-type wells, so that N-type ion-implanted regions 102A, 104A are formed. Specifically, for example, the N-type ion-implanted regions 102A are formed in the region of the P-type well 100A exposed through the opening 110A of the resist 110, and the N-type ion-implanted regions 104A are formed in the region of the P-type well 100A exposed through the opening 110B of the resist 110.

By this N-type ion-implantation, two N-type wells apart from each other are formed in the P-type well 100A formed in the semiconductor substrate 100 as shown in FIG. 1C. That is, the second well 102 of N-type and the fourth well 104 of N-type apart from each other are formed in the P-type well 100A. The regions of the P-type well 100A separated by the second well 102 of N-type and the fourth well 104 of N-type become the first well 101 of P-type and the third well 103 of P-type. Note that the region of the P-type well 100A sandwiched between the second well 102 of N-type and the fourth well 104 of N-type is the third well 103. That is, the first well 101 of P-type, second well 102 of N-type, third well 103 of P-type, and fourth well 104 of N-type are formed in that order along the surface of the semiconductor substrate 100.

Next, a resist 111 having an opening 111A is formed over the surfaces of the first well 101 of P-type, second well 102 of N-type, third well 103 of P-type, and fourth well 104 of N-type as shown in FIG. 1D. This resist 111 is formed so as to expose, through its opening 111A, the third well 103 of P-type and the boundaries between the third well 103 of P-type, and the second well 102 of N-type and the fourth well 104 of N-type.

N-type ions are implanted through the opening 111A of this resist 111, e.g., once to form an N-type well, so that an N-type ion-implanted region 105A is formed. Here, the N-type ion-implanted region 105A is formed at the bottom of the third well 103 of P-type so as to overlap the second well 102 of N-type and the fourth well 104 of N-type. That is, the N-type ion-implanted region 105A is formed at the bottom of the third well 103 of P-type so as to connect the second well 102 of N-type and the fourth well 104 of N-type.

The N-type ion-implanted region 105A is the region to become a first buried well 105. It is desirable that the ion-implantation for the N-type ion-implanted region 105A that is to become the first buried well 105 be performed, for example, with phosphorus (P) at a concentration of 5×10¹² cm⁻² or greater at an energy of 1.6 MeV to 2.2 MeV. By this means, forming the first buried well 105 at the bottom of the third well 103 is realized with less ion-implantation energy and suppressing a decrease in production quantity.

Finally, the resist 111 is removed as shown in FIG. 1E, and by undergoing appropriate heat treatment, a triple well is formed in the semiconductor substrate 100, which is constituted by the first buried well 105 of N-type connecting the second well 102 of N-type and the fourth well 104 of N-type and located at the bottom of the third well 103 of P-type together with the first well 101 of P-type, second well 102 of N-type, third well 103 of P-type, and fourth well 104 of N-type.

Thereafter, although not shown, semiconductor elements (e.g., transistors) are formed in this triple well.

In the method of manufacturing a semiconductor device according to the present embodiment described above, the P-type well 100A as an area of a first conductivity type is formed on the semiconductor substrate 100 as mentioned above. Next, the second well 102 and the fourth well 104 as two regions of a second conductivity type are formed apart from each other in the P-type well 100A. Then the first buried well 105 of N-type as a first buried region of the second conductivity type to connect the second well 102 and the fourth well 104 is formed at the bottom of the third well 103 (a region of the first conductivity type) sandwiched between the second well 102 and the fourth well 104. In this way, the triple well is formed in the semiconductor substrate 100.

As such, after the P-type ions are implanted into the entire surface of the semiconductor substrate 100 to form the P-type well 100A, by performing N-type ion implantation, the second well 102 of N-type and the fourth well 104 of N-type are formed. Hence, at the same time that the second well 102 and the fourth well 104 that are of the same conductivity type, N-type, are formed, the first well 101 and the third well 103 that are of the same conductivity type, P-type, are formed. Thus, the number of production process steps is reduced. Specifically, the triple well can be formed with fewer process steps than with, e.g., the technique disclosed in Patent Literature 4 (No. H10-199825) wherein multiple independent wells are formed individually.

Further, because P-type ions are implanted into the entire surface of the semiconductor substrate 100 to form the P-type well 100A, at this stage the carrier concentrations of the first well 101 of P-type and the third well 103 of P-type are already determined, and the carrier surface concentrations of the first well 101 and the third well 103 that are of the same conductivity type, P-type, do not differ. That is, the carrier surface concentration does not differ (i.e., has no difference) between the region of the first conductivity type (third well 103) sandwiched between the two spaced-apart regions of the second conductivity type (second well 102 and fourth well 104), and the other region of the first conductivity type (first well 101). Further, because the second well 102 and the fourth well 104 that are of the same conductivity type, N-type, are provided with their conductivity type by the same ion-implantation process, the carrier surface concentration does not differ. Thus, in the present embodiment, semiconductor elements (e.g., transistors) respectively formed in multiple independent wells have the same characteristics.

### Second Embodiment

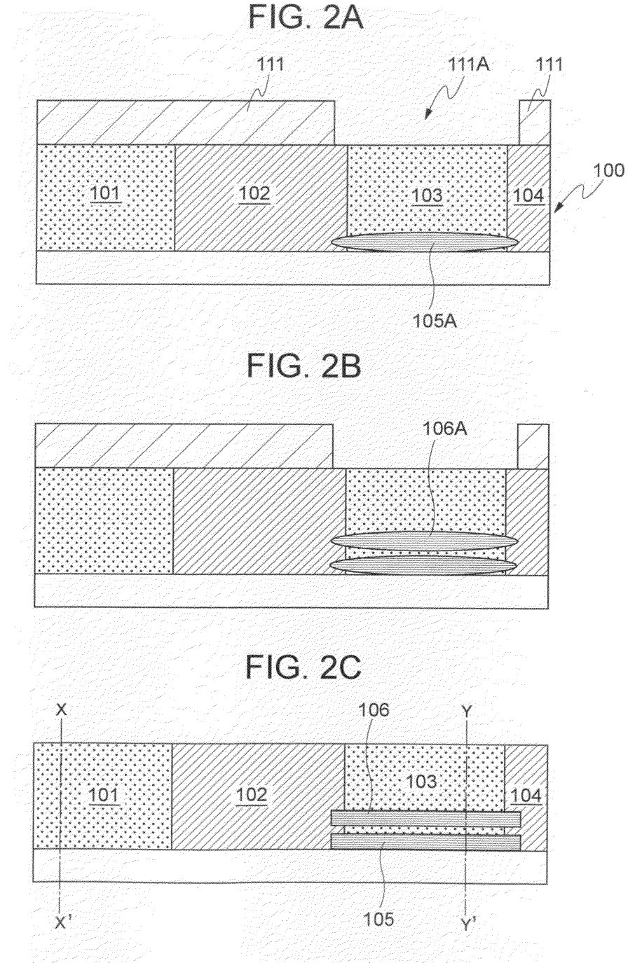

FIGS. 2A to 2C are a process chart showing the method of manufacturing a semiconductor device according to a second embodiment.

In the method of manufacturing a semiconductor device according to the second embodiment, first together with the first well 101 of P-type, second well 102 of N-type, third well 103 of P-type, and fourth well 104 of N-type, the N-type ion-implanted region 105A to become the first buried well 105 of N-type connecting the second well 102 of N-type and the fourth well 104 of N-type is formed at the bottom of the third well 103 of P-type as shown in FIG. 2A, in the same way as in the first embodiment.

Then, P-type ions are implanted through the opening 111A of this resist 111, e.g., once to form a P-type well (P-type well of a higher concentration than the third well 103 of P-type), so that a P-type ion-implanted region 106A is formed as shown in FIG. 2B. Here, the P-type ion-implanted region 106A is formed at the bottom of the third well 103 of P-type and above (on the surface side of) the N-type ion-implanted region 105A (first buried well 105 of N-type) so as to overlap the second well 102 of N-type and the fourth well 104 of N-type. That is, the P-type ion-implanted region 106A is formed at the bottom of the third well 103 of P-type so as to connect the second well 102 of N-type and the fourth well 104 of N-type.

While the N-type ion-implanted region 105A is the region to become the first buried well 105 of N-type, the P-type ion-implanted region 106A is the region to become the second buried well 106 of P-type. Note that the first buried well 105 of N-type (N-type ion-implanted region 105A) and the second buried well 106 of P-type (P-type ion-implanted region 106A) are formed apart from each other. It is desirable that the ion-implantation for the P-type ion-implanted region 106A that is to become the second buried well 106 be performed, for example, with boron (B) at a concentration of 2×10¹² cm⁻² to 5×10¹² cm⁻² at an energy of 300 keV to 500 keV. By this means, forming the second buried well 106 above the first buried well 105 at the bottom of the third well 103 is realized with less ion-implantation energy and suppressing a decrease in production quantity.

Finally, the resist 111 is removed as shown in FIG. 2C, and by undergoing appropriate heat treatment, a triple well is formed in the semiconductor substrate 100, which is constituted by the first buried well 105 of N-type connecting the second well 102 of N-type and the fourth well 104 of N-type and located at the bottom of the third well 103 of P-type, and the second buried well 106 of P-type connecting the second well 102 of N-type and the fourth well 104 of N-type and located above the first buried well 105 at the bottom of the third well 103 of P-type together with the first well 101 of P-type, second well 102 of N-type, third well 103 of P-type, and fourth well 104 of N-type.

In the method of manufacturing a semiconductor device according to the present embodiment described above, together with the first buried well 105 of N-type, the second buried well 106 of P-type of a higher concentration than the third well 103 to connect the second well 102 of N-type and the fourth well 104 of N-type is formed above the first buried well 105 of N-type at the bottom of the third well 103 of P-type.

With, for example, the technique for forming triple wells (wells of a triple structure) as proposed in Patent Literature 4 (No. H10-199825), triple wells (wells of a triple structure) are formed by the process described in Patent Literature 4, paragraphs 0019 through 0025. When semiconductor elements (e.g., transistors) are respectively formed in the surfaces of the well of the second conductivity type (second well) and of the well of the first conductivity type (third well) of the formed triple well, a depletion layer will extend from the drain layer of the formed semiconductor element (e.g., a transistor) in the well of the first conductivity type (third well), and the two depletion layers will connect to each other, resulting in the occurrence of a leak current between the well of the second conductivity type (second well) and the semiconductor element (e.g., a transistor). This problem is notable especially where a high voltage device (e.g., an NMOS transistor) is formed as the semiconductor element.

In order to prevent the occurrence of this leak current, the energy of ion-implantation for forming the well of the first conductivity type (third well) needs to be large (e.g., 2 MeV or greater) to make the well of the first conductivity type (third well) deeper so that the two depletion layers do not connect. However, if the ion-implantation energy is large (e.g., 2 MeV or greater), the throughput capacity of the ion implanting apparatus is generally reduced, and thus the production quantity of semiconductor devices is also reduced.

Accordingly, in the present embodiment, by forming the second buried well 106 of P-type above the first buried well 105 of N-type as described above, the extension of the depletion layers from the drain layer of the formed semiconductor element (e.g., a transistor) and the first buried well 105 is suppressed, thus preventing a leak current in the semiconductor element. In particular, even where a high voltage device is formed as the semiconductor element, a leak current can be prevented.

Further, also in the present embodiment, as in the first embodiment, the carrier surface concentrations of the first well 101 and the third well 103 that are of the same conductivity type, P-type, do not differ. Also, because the second well 102 and the fourth well 104 that are of the same conductivity type, N-type, are provided with their conductivity type by the same ion-implantation process, the carrier surface concentration does not differ. Thus, also in the present embodiment, semiconductor elements (e.g., transistors) respectively formed in multiple independent wells have the same characteristics.

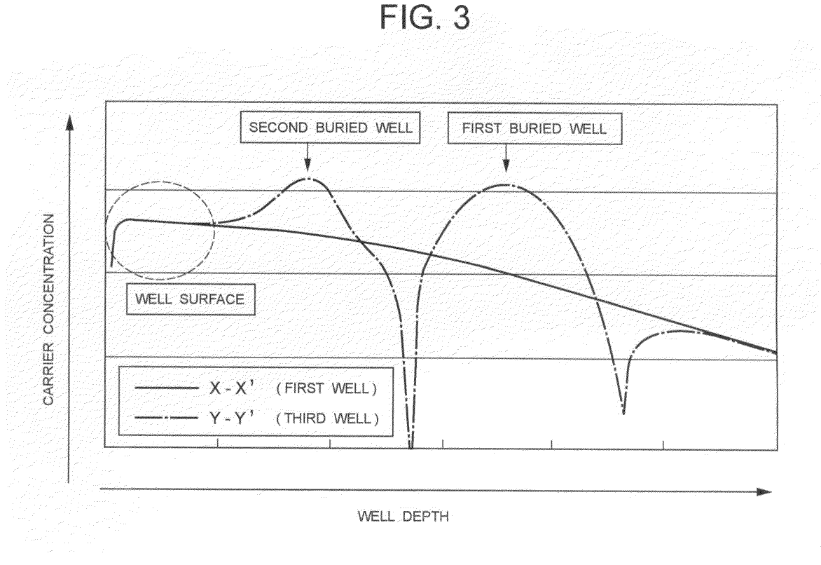

FIG. 3 shows the carrier concentration profile along line X-X′ of the first well and the carrier concentration profile along line Y-Y′ of the third well in the triple well obtained by the method of manufacturing a semiconductor device according to the second embodiment.

As shown in FIG. 3, it can be seen that the carrier concentration profiles near the well surface of the first well 101 of P-type and of the third well 103 of P-type are the same, that is, the surface concentration affecting electrical characteristics of semiconductor elements (e.g., transistors) does not differ. Hence, it can be seen that, for example, a first semiconductor element (e.g., a transistor) formed in the surface of the first well 101 of P-type and a second semiconductor element (e.g., a transistor) formed in the surface of the third well 103 exhibit the same electrical characteristics.

Although the above embodiments both describe the case where a P-type semiconductor substrate is used as the semiconductor substrate 100, by forming the well 100A, the first well 101, the third well 103, and the second buried well 106 by N-type ion-implantation and the second well 102, the fourth well 104, and the first buried well 105 by P-type ion-implantation, an N-type semiconductor substrate can be used as the semiconductor substrate 100.

None of the above embodiments is to be interpreted as limiting, and modified embodiments can be made within the scope of the present invention.

This application is based on Japanese Patent Application No. 2008-248330 which is incorporated herein by reference.

What is claimed is:

1. A method of manufacturing a semiconductor device, comprising the steps of:
forming an area of a first conductivity type on a semiconductor substrate;
forming two regions of a second conductivity type apart from each other in said area of the first conductivity type; and
forming a first buried region of the second conductivity type to connect said two regions of the second conductivity type at the bottom of part of said area of the first conductivity type sandwiched between said two regions of the second conductivity type that are spaced apart.

2. A method of manufacturing a semiconductor device according to claim 1, further comprising the step of:
forming a second buried region of the first conductivity type to connect said two regions of the second conductivity type above said first buried region of the second conductivity type at the bottom of the part of said area of the first conductivity type sandwiched between said two regions of the second conductivity type that are spaced apart.

3. A method of manufacturing a semiconductor device according to claim 1, wherein said first buried region is formed by implanting phosphorus (P) at a concentration of 5×10¹² cm⁻² or greater at an energy of 1.6 MeV to 2.2 MeV.

4. A method of manufacturing a semiconductor device according to claim 2, wherein said second buried region is formed by implanting boron (B) at a concentration of 2×10¹² cm⁻² to 5×10¹² cm⁻² at an energy of 300 keV to 500 keV.

5. A method of manufacturing a semiconductor device according to claim 1, wherein a carrier surface concentration has no difference between a region of said area of the first conductivity type formed on said semiconductor substrate, sandwiched between said two regions of the second conductivity type that are spaced apart, and another region of said area of the first conductivity type.
